(19) United States
(12) Patent Application Publication
(10) Pub. No.: US 2005/0153511 A1
(43) Pub. Date: Jul. 14, 2005

(54) Methods of fabricating nonvolatile memory device

(75) Inventor: Jin Hyo Jung, Bucheon-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DongbuAnam Semiconductor Inc.

(21) Appl. No.: 11/024,436

(22) Filed: Dec. 30, 2004

(30) Foreign Application Priority Data
Dec. 31, 2003 (KR) 10-2003-0101098

(51) Int. Cl. H01L 21/336; H01L 21/3205; H01L 21/4763

(52) U.S. Cl. 438/257; 438/593

(57) ABSTRACT

A fabricating method of nonvolatile memory devices is disclosed. A disclosed method comprises: forming a buffer oxide layer and a buffer nitride layer on the entire surface of a semiconductor substrate and performing a patterning process; forming a sidewall floating gates on the sidewalls of the patterned buffer nitride layer; forming a block oxide layer on the entire surface of the substrate; removing the block oxide layer and the sidewall floating gates deposited on the field region after the substrate is patterned and the field region is opened; depositing a polysilicon layer on the entire surface of the substrate and performing a patterning process to form a word line; forming sidewall spacers on the sidewalls of the sidewall floating gates and the word line; and forming source and drain regions by implanting dopants into the substrate.

### BACKGROUND OF THE INVENTION

1. Field of the Invention

The present invention relates to a fabricating method of a nonvolatile memory device and, more particularly, to a fabricating method of a nonvolatile memory device which can effectively embody NOR flash cell arrays comprising 2-bit sidewall floating gate devices, which have a self-convergence characteristic that a threshold voltage converges to a certain value during an erase operation.

2. Background of the Related Art

In general, there are two categories in semiconductor devices, namely, a volatile memory and a non-volatile memory. The volatile memory again includes a dynamic random access memory (hereinafter referred to as “DRAM”) and a static DRAM (hereinafter referred to as “SDRAM”). One characteristic of the volatile memory is that data are maintained just while electric power is being applied. In other words, when power is turned off, the data in the volatile memory disappear. On the other hands, the non-volatile memory, mainly a ROM (Read Only Memory), can keep the data regardless of the application of electric power.

From the point of a view of the fabrication process, the non-volatile memory is divided into a floating gate type and a metal insulator semiconductor (hereinafter referred to as “MIS”) type. The MIS type has doubly or triply deposited dielectric layers which comprise at least two kinds of dielectric materials.

The floating gate type stores data using potential wells, and is represented by an ETOX (Electrically erasable programmable read only memory Tunnel OXide) used in a flash EEPROM (Electrically Erasable Programmable Read Only Memory).

The MIS type performs the program operation using traps at a bulk dielectric layer, an interface between dielectric layers, and an interface between a dielectric layer and a semiconductor. Metal/Silicon ONO Semiconductor (hereinafter referred to as “MONOS/SONOS”) structure mainly used for the flash EEPROM is representative MIS structure.

FIG. 1 is a cross-sectional view illustrating a flash memory cell manufactured in accordance with the prior art. A gate oxide layer 12 is formed on a semiconductor substrate 10 where a device isolation structure 11 is formed. A first polysilicon layer 13 for a floating gate is then formed on the gate oxide layer 12. A dielectric layer 15 and a second polysilicon layer 16 are formed sequentially on the floating gate 13, and the second polysilicon layer 16 is used as a control gate. Next, after a metal layer 17 and a nitride layer 18 are deposited sequentially on the control gate 16, all the layers are patterned in cell structure to complete a flash memory cell.

For the present fabricating process of NOR flash memories, a self-aligned source(hereinafter referred to as “SAS”) or a self-aligned shallow trench isolation(hereinafter referred to as “SA-STI”) process is chiefly adopted to minimize the unit cell area of the NOR flash memories. Although the SAS or the SA-STI process or even both processes are applied, the unit cell area cannot be reduced down to the minimum area(4F²) of a NAND flash cell, because a bit contact should be formed.

### SUMMARY OF THE INVENTION

Accordingly, the present invention is directed to a fabricating method of nonvolatile memory devices that substantially obviates one or more problems due to limitations and disadvantages of the related art.

An object of the present invention is to provide a fabricating method of the nonvolatile memory devices which embodies the effective fabrication of a NOR flash cell array which comprises 2-bit sidewall floating gate devices having the self-convergence characteristic that a threshold voltage converges to a certain value during an erase operation, making a NOR flash unit cell with 4F² area. Furthermore, the unit cell area can be reduced down to 2F² if the NOR flash unit cell operates in a multi-level bit by using the self-convergence characteristic of a threshold voltage and the select gate characteristic of a main gate.

To achieve these objects and other advantages and in accordance with the purpose of the invention, as embodied and broadly described herein, a fabricating method of nonvolatile memories comprises: forming a buffer oxide layer and a buffer nitride layer on the entire surface of a semiconductor substrate and performing a patterning process; forming a sidewall floating gates on the sidewalls of the patterned buffer nitride layer; forming a block oxide layer on the entire surface of the substrate; removing the block oxide layer and the sidewall floating gates deposited on the field region after the substrate is patterned and the field region is opened; depositing a polysilicon layer on the entire surface of the substrate and performing a patterning process to form a word line; forming sidewall spacers on the sidewalls of the sidewall floating gates and the word line; and forming source and drain regions by implanting dopants into the substrate.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings;

FIG. 1 is a cross-sectional view illustrating a flash memory cell manufactured in accordance with the prior art.

FIG. 2 is drawings comparing unit cell areas of a NOR flash memory according to the prior art and a nonvolatile memory device according to the present invention.

FIG. 3 is a top view illustrating the cell array layout of a nonvolatile memory device.

FIGS. 4a through 4h are cross-sectional views illustrating example processes of fabricating nonvolatile memory devices according to an embodiment of the present invention.

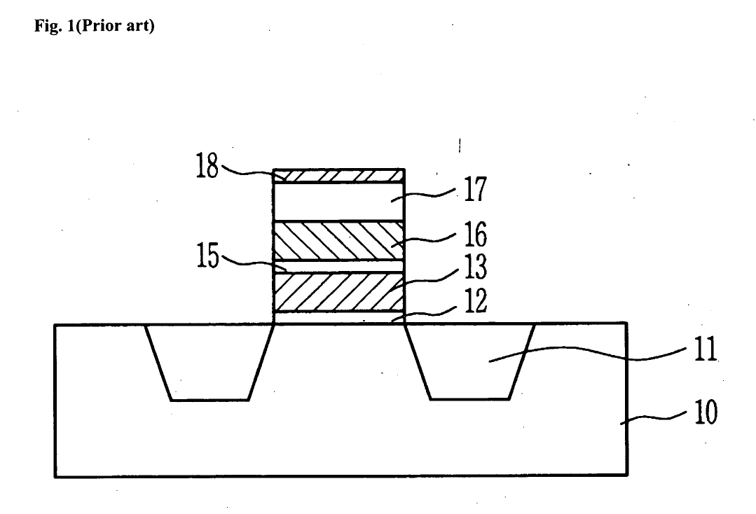

### DETAILED DESCRIPTION OF THE PREFERRED EMBODIMENT

Reference will now be made in detail to the preferred embodiments of the present invention, examples of which are illustrated in the accompanying drawings.

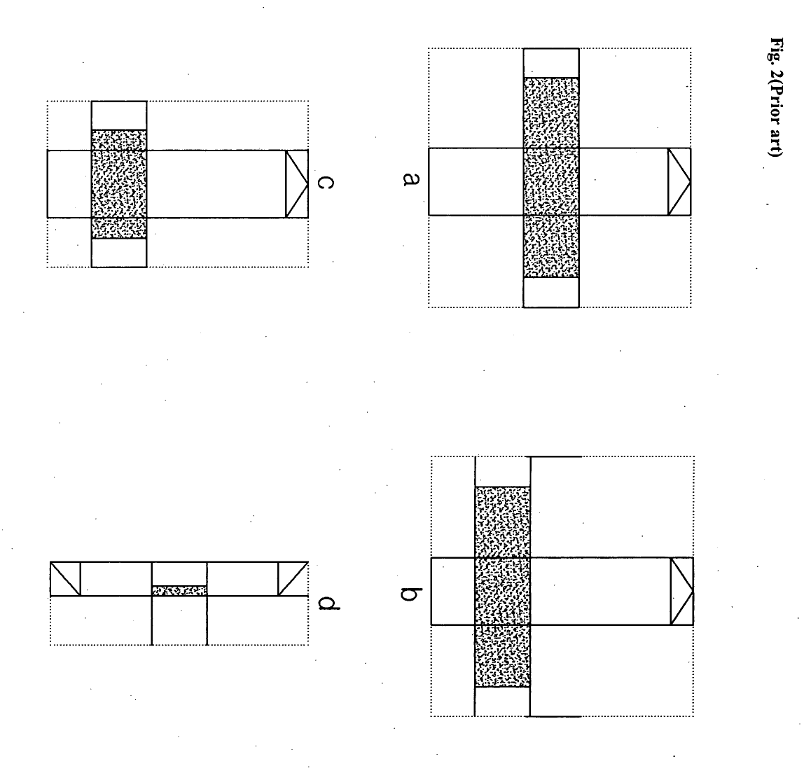

Referring to FIG. 2-a, a NOR flash unit cell area is about 10.5F² when both a SAS and a SA-STI process are not applied.

Referring to FIG. 2-b, a NOR flash unit cell area is about 9F² when a SAS process is applied but a SA-STI process is. Thus, the cell area can be reduced by about 15% more than that in FIG. 2a due to the SAS process.

Referring to FIG. 2-c, a NOR flash unit cell area is about 6F² when both a SAS and a SA-STI process are applied. Thus, the cell area can be reduced by about 43% and 33% more than that in FIG. 2-a and that in FIG. 2-b respectively.

Referring to FIG. 2-d, a NOR flash unit cell comprising 2-bit sidewall floating gate devices has a unit cell area of about 4F in accordance with the present invention. Also, if the NOR flash memory is operated in a multi-level bit by using the self-convergence characteristic of the threshold voltage during an erase operation and the select gate characteristic of a main gate, the cell area can be reduced down to 2F² because 4 bits can be embodied in a single transistor. The 2F corresponds to a half of a NAND flash unit cell area(4 F ) using a SA-STI process. Thus, the cell area can be reduced by about 81%, 78% and 67% as compared to that in FIG. 2-a, that in FIG. 2-b and that in FIG. 2-c respectively.

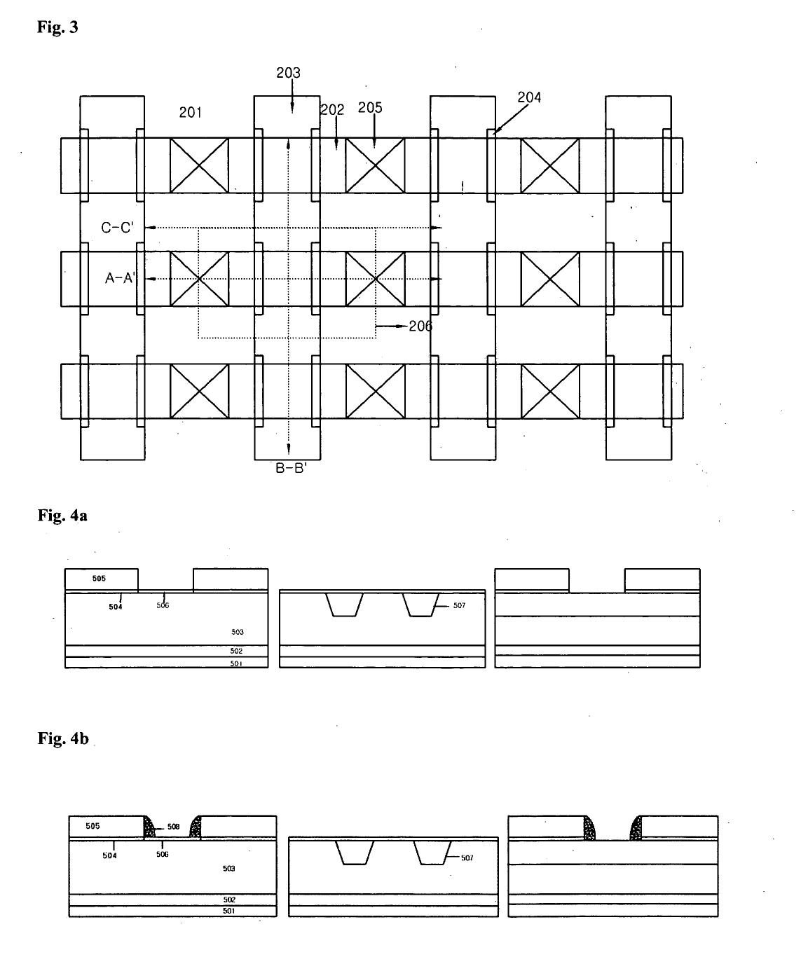

Referring to FIG. 3, shallow trench isolation(hereinafter referred to as “STI”) areas 201, active areas 202, word lines 203, sidewall floating gates 204, bit line contacts 205 and unit cell 206 are shown.

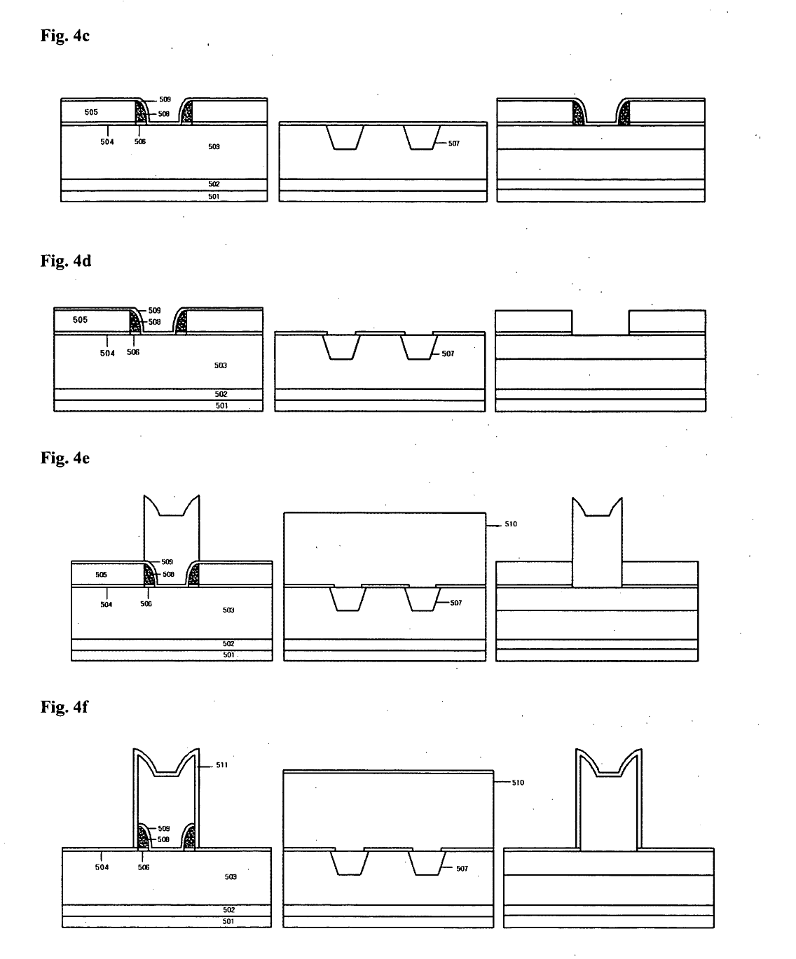

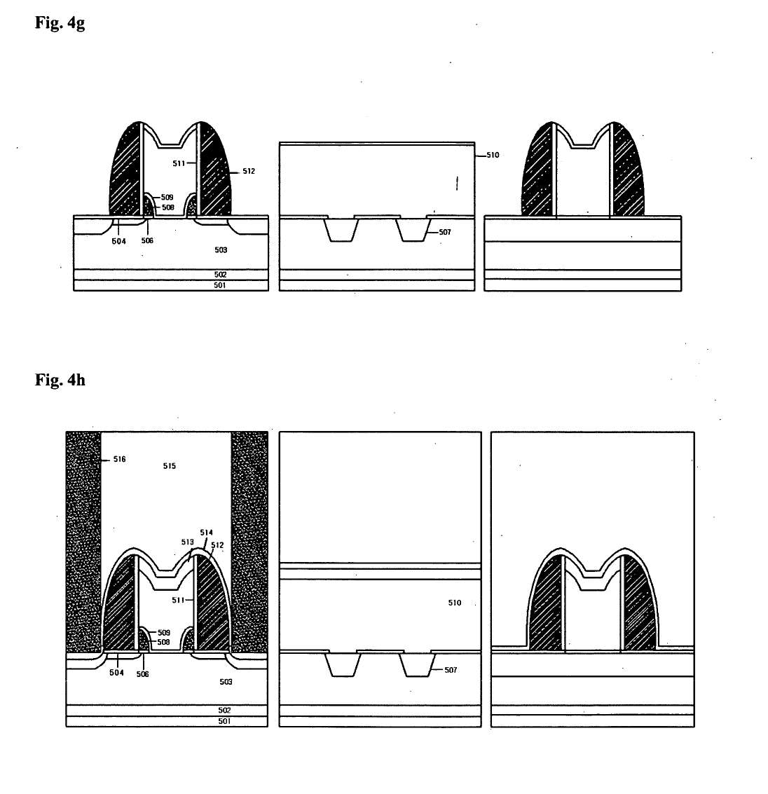

Cross-sectional views along the line, A-A′, the line B-B′ and the line C-C′ are described in FIGS. 4a through 4h, each from left to right.

Referring to FIG. 4a, a device isolation structure 507 is formed through an STI process in a P-type semiconductor substrate 501. Next, a deep N-type well 502 and a P-type well 503 are formed respectively in the semiconductor substrate 501 by using an ion implantation process. When the P-type well is formed, ion implantations for adjusting a threshold voltage and/or preventing a punch-through may be additionally performed. A buffer oxide layer 504 is then grown or deposited on the substrate and a buffer nitride layer 505 is deposited on the buffer oxide layer 504. Here, the oxide layer used in the ion implantation process for well formation may be used instead of the buffer oxide layer 504. The buffer nitride layer 505 and the buffer oxide layer 504 are patterned along a word line. A tunnel oxide layer 506 is formed on the silicon substrate exposed after the patterning process. Preferably, the buffer oxide layer 504 is grown or deposited with a thickness between 50 Å and 300 Å and the buffer nitride layer 505 is deposited with a thickness between 100 Å and 2000Å, and the tunnel oxide layer is grown or deposited with a thickness between 30 Å and 300 Å.

Referring to FIG. 4b, after a polysilicon layer is deposited on the entire surface of the substrate, side-wall floating gates 508 are formed on the sidewalls of the buffer nitride layer 505 through a blanket etching process. Preferably, the polysilicon layer is deposited with a thickness between 100 Å and 1500 Å.

Referring to FIG. 4c, after the tunnel oxide layer 506 which is formed on the exposed silicon substrate is removed, a block oxide layer 509 is formed on the entire surface of the substrate. The block oxide layer 509 has multi-layered structure of a first block oxide layer and a second block oxide layer. The first and the second block oxide layers deposited on the sidewall floating gates make a threshold voltage converge to a predetermined value during an erase operation. And, the first and the second block oxide layers deposited on the silicon substrate are used as a main gate oxide layer. Preferably, Al₂O₃ or Y₂O₃ is deposited with a thickness between 40 Å and 400 Å for the first block oxide layer, and SiO₂ is deposited with a thickness between 20 Å and 200 Å for the second block oxide layer.

Referring to FIG. 4d, the first block oxide layer, the second block oxide layer and the sidewall floating gates on the field region are removed by performing an etching process after the field region(the line C-C′ in FIG. 3) is opened through a patterning process.

Referring to FIG. 4e, after a polysilicon layer 510 is deposited on the entire surface of the substrate, a word line(i.e., polysilicon main gate) is formed by performing a patterning process. Here, doped polysilicon may be used for the polysilicon layer 510 or after undoped polysilicon is deposited on the entire surface of the substrate, the undoped polysilicon layer may be doped through an ion implantation process. The thickness of the polysilicon layer 510 is preferably between 500 Å and 4000 Å.

Referring to FIG. 4f, after the buffer nitride layer 505 is removed by a wet etch, a poly oxide layer 511 is grown or deposited by using a CVD(chemical vapor deposition) process on the surface of the word line and the sidewalls of the sidewall floating gates.

Referring to FIG. 4g, an ion implantation process is performed by using the word line as a mask to form LLD(lightly doped drain) regions or source and drain diffusion regions. After an insulation layer is deposited on the entire surface of the substrate, a blanket etching process is performed to form sidewall spacers 512 on the sidewalls of the word line. Next, an ion implantation process is performed by using both the word line and the sidewall spacers as masks to form source and drain regions. Preferably, the sidewall spacers are made of an oxide layer or a nitride layer or both an oxide layer and a nitride layer. If necessary, a silicide process may be skipped for the source and drain regions.

Referring to FIG. 4h, as in the prior art, a silicide layer 513 is selectively formed only on, the word line and the source and drain regions through a silicide process. After an etching stop layer 514 and an insulation layer 515 are deposited in order on both the silicide layer 13 and the sidewall spacers, a planarization process is carried out. through a CMP(chemical mechanical polishing) process or an etch back process, thereby a contact plug 516 and a metal electrode are formed.

Accordingly, the disclosed method can effectively embody NOR flash memory cells comprising 2-bit sidewall floating gate devices with a self-convergence characteristic, thereby the unit cell area of the NOR flash memory is reduced to 4F². Also, the illustrated method can operate a NOR flash memory cell in a multi-level bit by using the select gate characteristic of a main gate and the self-convergence characteristic of a threshold voltage during an erase operation. As a result, the unit cell area can be reduced down to 2F². Thus, the unit cell area of the NOR flash memory is reduced by 67% to 81% in comparison with that of the prior art and the density of flash memories is greatly increased through the present invention.

It is noted that this patent claims priority from Korean Patent Application Serial Number 10-2003-0101098, which was field on Dec. 31, 2003, and is hereby incorporated by reference in its entirety.

The foregoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

1. A fabricating method of a nonvolatile memory comprising the steps of:
forming a buffer oxide layer and a buffer nitride layer on the entire surface of a semiconductor substrate and performing a patterning process;
forming sidewall floating gates on the sidewalls of the patterned buffer nitride layer;
forming a block oxide layer on the entire surface of the substrate;
removing the block oxide layer and the sidewall floating gates deposited on the field region after the substrate is patterned and the field region is opened;
depositing a polysilicon layer on the entire surface of the substrate and performing a patterning process to form a word line;
forming sidewall spacers on the sidewalls of the sidewall floating gates and the word line; and
forming source and drain regions by implanting dopants into the substrate.

2. A method as defined by claim 1, wherein the buffer oxide layer is formed with a thickness between 50 Å and 300 Å.

3. A method as defined by claim 1, wherein the buffer nitride layer is formed with a thickness between 100 Å and 2000 Å.

4. A method as defined by claim 1, wherein the polysilicon layer is formed with a thickness between 500 Å and 4000 Å.

5. A method as defined by claim 1, wherein the block oxide layer has a multi-layered structure comprising a first block oxide layer and a second block oxide layer.

6. A method as defined by claim 5, wherein the first block oxide layer is made of Al₂O₃ or Y₂O₃ with a thickness between 40 Å and 400 Å.

7. A method as defined by claim 5, wherein the second block oxide layer is made of SiO₂ with a thickness between 20 Å and 200 Å.

8. A method as defined by claim 1, further comprising the step of removing the buffer nitride layer, and forming an oxide layer on the surface of the word line and the sidewalls of the sidewall floating gates prior to the formation of the sidewall spacers.
